(19) United States
(12) Patent Application Publication
(10) Pub. No.: US 2025/0142729 A1
(43) Pub. Date: May 1, 2025

(54) ELECTRONIC DEVICE

(71) Applicant: Samsung Display Co., Ltd., Yongin-si (KR)

(72) Inventors: Youngjin Park, Yongin-si (KR); Jooyoung Kim, Yongin-si (KR); Youngjoo Nam, Yongin-si (KR); Dohyun Park, Yongin-si (KR)

(73) Assignee: Samsung Display Co., Ltd., Yongin-si (KR)

(21) Appl. No.: 18/770,005

(22) Filed: Jul. 11, 2024

(30) Foreign Application Priority Data
Oct. 30, 2023 (KR) 10-2023-0146993

(51) Int. Cl. H05K 1/18

(52) U.S. Cl. CPC H05K 1/181; H05K 2201/10128; H05K 2201/10371; H05K 2201/2018

(57) ABSTRACT

An electronic device includes a display panel, a circuit board, on which at least one component is mounted and connected to the display panel, and a cover portion coupled to the circuit board and shield the at least one component. The cover portion includes a coupling portion that protrudes, the circuit board includes a receiving portion coupled to the coupling portion, and the coupling portion is accommodated in the receiving portion.

### CROSS-REFERENCE TO RELATED APPLICATION(S)

This application claims priority to and benefits of Korean Patent Application No. 10-2023-0146993 under 35 U.S.C. § 119, filed on Oct. 30, 2023, in the Korean Intellectual Property Office (KIPO), the entire contents of which are incorporated herein by reference.

### BACKGROUND

### 1. Technical Field

The disclosure relates to an electronic device including a display panel and capable of displaying an image.

### 2. Description of the Related Art

Electronic devices have been variously used as mobile electronic devices and fixed electronic devices. Such electronic devices include display apparatuses that may provide visual information such as images or videos to users to support various functions.

A display apparatus may include a substrate divided into a display area and a peripheral area. In the display area, a scan line and a data line may be formed to be insulated from each other, and a plurality of pixels may be provided. Also, in the display area, a thin-film transistor corresponding to each of the pixels and a pixel electrode electrically connected to the thin-film transistor may be provided. Additionally, in the display area, a counter electrode may be provided in common to the pixels. In the peripheral area, various wirings for transmitting electrical signals to the display area, a scan driving unit, a data driving unit, a control unit, and a pad unit may be provided.

### SUMMARY

A display apparatus may include a printed circuit board (PCB) for transmitting an electrical signal. Various types of chip components may be mounted on the PCB. In order to block electromagnetic waves generated from these components, a shield can for shielding the components may be located on the PCB. The shield can may be fixed to the PCB through soldering. A part of the soldered shield can may be separated from the PCB. One or more embodiments include an electronic device that prevents a shield can from falling off from a PCB.

Additional aspects will be set forth in part in the description which follows and, in part, will be apparent from the description, or may be learned by practice of the embodiments.

According to an embodiment, an electronic device may include a display panel, a circuit board, on which at least one component is mounted and connected to the display panel, and a cover portion coupled to the circuit board and shield the at least one component. The cover portion may include a coupling portion that protrudes, the circuit board may include a receiving portion coupled to the coupling portion, and the coupling portion may be accommodated in the receiving portion.

The electronic device may further include a first support portion located between the coupling portion and the receiving portion.

The first support portion may include gold (Au).

The circuit board may include a plurality of layers including different materials, and the receiving portion may pass through at least one of the plurality of layers.

The electronic device may further include a second support portion located between the coupling portion and the first support portion.

The first support portion and the second support portion may include different materials.

The second support portion may be spaced apart from the circuit board.

The circuit board may further include a tip protruding toward the receiving portion.

At least a portion of the coupling portion may be bent.

The coupling portion may include a first coupling portion and a second coupling portion bent from a part of the coupling portion in different directions.

At least a part of the first coupling portion may be located below a first tip protruding from a side surface of the circuit board facing the receiving portion toward the receiving portion, and at least a part of the second coupling portion may be located below a second tip facing the first tip with the receiving portion between the first tip and the second tip.

The coupling portion may include a plurality of coupling portions, the receiving portion may include a plurality of receiving portions, the plurality of coupling portions may be spaced apart from each other, and the plurality of receiving portions may be arranged to respectively correspond to the plurality of coupling portions.

According to an embodiment, an electronic device may include a display panel, a circuit board, on which at least one component is mounted and connected to the display panel, a cover portion coupled to the circuit board, shield the at least one component, and including a coupling portion protruding toward the circuit board, and a first support portion located between the coupling portion and the circuit board. In a plan view, the first support portion may include a first protrusion protruding from a first end of the first support portion in a first direction in which the first support portion extends toward a second direction different from the first direction, and a second protrusion protruding from a second end of the first support portion opposite to the first end toward a direction opposite to the second direction.

The first direction and the second direction may be perpendicular to each other.

An area of the first protrusion and an area of the second protrusion may be equal to each other in a plan view.

The first support portion may include gold (Au).

The electronic device may further include a second support portion located on the first support portion and surrounding a part of a side surface of the coupling portion.

The first support portion and the second support portion may include different materials.

The second support portion may include a first portion overlapping the first protrusion and a second portion overlapping the second protrusion in a plan view.

The coupling portion may include a plurality of coupling portions, the first support portion may include a plurality of first support portions, the plurality of coupling portions may be spaced apart from each other, and the plurality of first support portions may be arranged to respectively correspond to the plurality of coupling portions.

### BRIEF DESCRIPTION OF THE DRAWINGS

The above and other aspects, features, and advantages of certain embodiments will be more apparent from the following description taken in conjunction with the accompanying drawings, in which:

FIG. 1 is a plan view schematically illustrating an electronic device, according to an embodiment;

FIG. 2 is a schematic cross-sectional view illustrating a portion of a display area of an electronic device, according to an embodiment;

FIG. 3 is an exploded perspective view schematically illustrating a display circuit board, according to an embodiment;

FIG. 4 is a schematic cross-sectional view illustrating a state where a cover portion and a circuit board are coupled to each other, according to a first embodiment;

FIGS. 5A to 5D are cross-sectional views illustrating a process of manufacturing an electronic device, according to the first embodiment;

FIG. 6 is an enlarged perspective view illustrating a part of a cover portion, according to a second embodiment;

FIG. 7 is a schematic cross-sectional view illustrating a state where a coupling portion and a circuit board are coupled to each other, according to the second embodiment;

FIG. 8 is a plan view illustrating a state where a cover portion and a circuit board are coupled to each other, according to the second embodiment;

FIGS. 9A to 9D are schematic cross-sectional views illustrating a process of manufacturing an electronic device, according to the second embodiment;

FIG. 10 is a perspective view illustrating a state where a cover portion and a circuit board are coupled to each other, according to a third embodiment; and

FIGS. 11A to 11F are plan views illustrating a state where a cover portion and a circuit board are coupled to each other, according to various embodiments.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be understood that the terms “including,” and “having,” are intended to indicate the existence of the features or elements described in the specification, and are not intended to preclude the possibility that one or more other features or elements may exist or may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Sizes of components in the drawings may be exaggerated or reduced for convenience of explanation. For example, because sizes and thicknesses of elements in the drawings are arbitrarily illustrated for convenience of explanation, the disclosure is not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be different from the described order. For example, two consecutively described processes may be performed substantially at the same time or may be performed in an order opposite to the described order.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

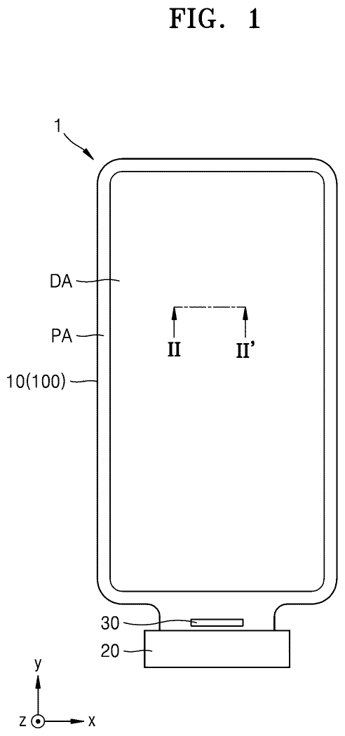

FIG. 1 is a plan view schematically illustrating an electronic device 1, according to an embodiment.

An electronic device according to an embodiment may be a display apparatus, for example, an organic light-emitting display apparatus. The following will be illustrated and described based on an embodiment that an electronic device is a display apparatus, but characteristic structures of the disclosure are not necessarily limited to a display apparatus.

Referring to FIG. 1, the electronic device 1 for displaying a moving image or a still image according to an embodiment may be used as a display screen of not only a portable electronic device such as a mobile phone, a smartphone, a tablet personal (PC) computer, a mobile communication terminal, an electronic organizer, an electronic book, a portable multimedia player (PMP), a navigation device, or an ultra-mobile PC (UMPC) but also any of various products such as a television, a laptop computer, a monitor, an advertisement board, or an Internet of things (IoT) product. Also, the electronic device 1 may be used in a wearable device such as a smart watch, a watch phone, a glasses-type display, or a head-mounted display (HMD). Also, the electronic device 1 may be used as a center information display (CID) located on an instrument panel, a center fascia, or a dashboard of a vehicle, a room mirror display replacing a side-view mirror of a vehicle, or a display located on the back of a front seat for entertainment for a person in a back seat of a vehicle.

The electronic device 1 may include a display panel 10, a display circuit board 20, and a display driving unit 30. The electronic device 1 may further include a bracket, a main circuit board, a battery, and a lower cover which are not shown.

In a direction (e.g., a +z direction) perpendicular to a surface of the electronic device 1, the electronic device 1 may have a substantially rectangular shape as shown in FIG. 1. For example, as shown in FIG. 1, the electronic device 1 may have a substantially rectangular planar shape having a short side extending in a ±x direction and a long side extending in a ±y direction. A corner where the short side in the ±x direction and the long side in the ±y direction meet each other may have a round shape with a curvature or a shape with a right angle. However, a planar shape of the electronic device 1 is not limited to a rectangular shape, and may be another polygonal shape, a circular shape, or an elliptical shape.

The display panel 10 may display (output) information processed by the electronic device 1. For example, the display panel 10 may display execution screen information of an application driven by the electronic device 1 or user interface (UI) or graphical user interface (GUI) information according to the execution screen information. The display panel 10 may include a display layer for displaying an image and a touch layer for detecting a user's touch input. Accordingly, the display panel 10 may function as one of input devices that provide an input interface between the electronic device 1 and the user and may also function as one of output units that provide an output interface between the electronic device 1 and the user.

The display panel 10 may include a substrate 100 and display devices located on the substrate 100. The substrate 100 included in the display panel 10 may include an insulating material such as glass, quartz, or a polymer resin.

The substrate 100 may include a display area DA and a peripheral area PA adjacent to the display area DA, and the display devices may be located in the display area DA of the substrate 100.

The peripheral area PA of the substrate 100 may be an area where an image is not displayed. The peripheral area PA may surround the display area DA in a plan view. The peripheral area PA may be an area from an edge of the display area DA to an edge of the display panel 10. In the display area DA, not only pixels but also scan wirings, data wirings, and power supply wirings connected to the pixels may be located. In the peripheral area PA, a scan driving unit for applying scan signals to the scan wirings, and fan-out wirings that connect the data wirings to the display driving unit 30 may be located.

The display devices may include, for example, light-emitting elements. For example, the display panel 10 may be an organic light-emitting display panel using an organic light-emitting diode including an organic emission layer, a micro light-emitting diode display panel using a micro light-emitting diode (LED), a quantum dot light-emitting display panel using a quantum dot light-emitting diode including a quantum dot emission layer, or an inorganic light-emitting display panel using an inorganic light-emitting device including an inorganic semiconductor.

The display panel 10 may be a rigid display panel that is rigid and does not bend readily, or a flexible display panel that is flexible and may be readily bent, folded, or rolled. For example, the display panel 10 may be a foldable display panel that may be folded and unfolded, a curved display panel with at least a portion of a display surface curved, a bended display panel in which a portion other than a display surface is bent, a rollable display panel that may be rolled up or unfolded, or a stretchable display panel that may be stretched.

The display circuit board 20 may be electrically connected to the display panel 10. The display circuit board 20 may be a flexible printed circuit board (FPCB) that may be bent or a rigid printed circuit board (PCB) that is hard and thus does not bend readily, or in another embodiment, the display circuit board 31 may be a composite PCB including both a rigid PCB and an FPCB. Although not shown in FIG. 1, various electronic components may be mounted on the display circuit board 20, and a cover portion for shielding at least some of the electronic components may be provided.

The display driving unit 30 may receive control signals and power supply voltages, and may generate and output signals and voltages for driving the display panel 10. The display driving unit 30 may include an integrated circuit (IC).

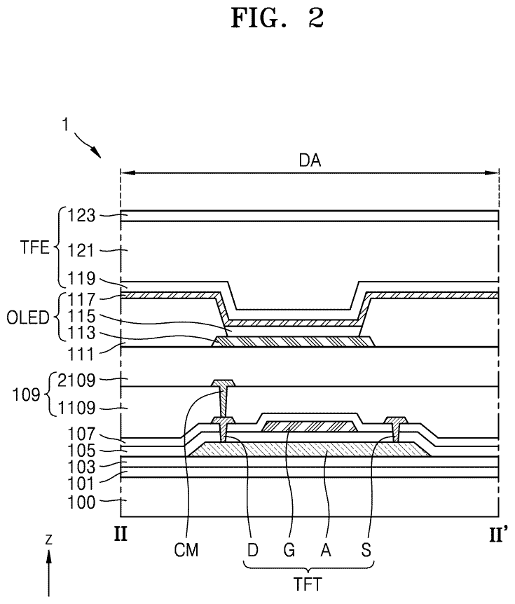

FIG. 2 is a schematic cross-sectional view illustrating a portion of the display area DA of the electronic device 1, according to an embodiment. FIG. 2 is a schematic cross-sectional view illustrating the electronic device 1 taken along line II-II′ of FIG. 1.

Referring to FIG. 2, an organic light-emitting diode OLED as a display element may be located on the substrate 100. The organic light-emitting diode OLED may be electrically connected to a thin-film transistor TFT.

A barrier layer 101 and a buffer layer 103 may be located on the substrate 100. The barrier layer 101 and the buffer layer 103 may planarize and protect a top surface of the substrate 100. Each of the barrier layer 101 and the buffer layer 103 may include an inorganic insulating material such as silicon oxide (SiOₓ), silicon nitride (SiNₓ), and/or silicon oxynitride (SiON).

The thin-film transistor TFT may be located on the buffer layer 103. The thin-film transistor TFT may include an active layer A, a gate electrode G, a source electrode S, and a drain electrode D. The thin-film transistor TFT may be connected to the organic light-emitting diode OLED to drive the organic light-emitting diode OLED.

The active layer A may be located on the buffer layer 103, and may include a drain region overlapping the drain electrode D in a plan view, a source region overlapping the source electrode S in a plan view, and a channel region located between the drain region and the source region. The drain region and the source region may be regions doped with impurities.

A gate insulating layer 105 may be located on the active layer A. The gate insulating layer 105 may include an inorganic material including oxide or nitride. For example, the gate insulating layer 105 may include at least one of silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single or multi-layer structure including the above material.

The gate electrode G may be located on the gate insulating layer 105. At least a part of the gate electrode G may overlap the active layer A in a plan view. For example, the gate electrode G may overlap the channel region of the active layer A in a plan view. The gate electrode G may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single or multi-layer structure including the above material.

An interlayer insulating layer 107 may cover the gate electrode G. The interlayer insulating layer 107 may include an inorganic material including oxide or nitride. For example, the interlayer insulating layer 107 may include at least one of silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single or multi-layer structure including the above material.

The gate insulating layer 105 and the interlayer insulating layer 107 may include contact holes overlapping the source region and the drain region of the active layer A in a plan view. The source electrode S and the drain electrode D may be located on the interlayer insulating layer 107. The source electrode S may overlap the source region of the active layer A in a plan view, and the drain electrode D may overlap the drain region of the active layer A in a plan view. The source electrode S and the drain electrode D may be connected to the active layer A through the contact holes formed in the gate insulating layer 105 and the interlayer insulating layer 107.

An organic insulating layer 109 may be located on the interlayer insulating layer 107. The organic insulating layer 109 may include first and second organic insulating layers 1109 and 2109. In an embodiment, the first organic insulating layer 1109 and the second organic insulating layer 2109 may be sequentially located on the interlayer insulating layer 107. Each of the first and second organic insulating layers 1109 and 2109 may include an opening overlapping the drain electrode D in a plan view. A connection metal CM may be located between the first and second organic insulating layers 1109 and 2109.

The connection metal CM may include aluminum (AI), copper (Cu), and/or titanium (Ti), and may have a single or multi-layer structure including the above material.

Each of the first and second organic insulating layers 1109 and 2109 may include benzocyclobutene, polyimide, hexamethyldisiloxane, a general-purpose polymer such as polymethylmethacrylate or polystyrene, a polymer derivative having a phenol-based group, an acrylic polymer, an imide-based polymer, an aryl ether-based polymer, an amide-based polymer, a fluorine-based polymer, a p-xylene-based polymer, or a vinyl alcohol-based polymer, and may have a single or multi-layer structure including the above material.

Although two organic insulating layers and one connection metal are illustrated in FIG. 2, the disclosure is not necessarily limited thereto. In another embodiment, one organic insulating layer may be provided, and the connection metal may be omitted. In another embodiment, three or more organic insulating layers may be provided, and two or more connection metals may be provided.

A sub-pixel electrode 113 may be located on the organic insulating layer 109. For example, the sub-pixel electrode 113 may be located on the second organic insulating layer 2109. Although not shown in FIG. 2, the sub-pixel electrode 113 may be connected to the connection metal CM through an opening of the second organic insulating layer 2109. Accordingly, the sub-pixel electrode 113 may be electrically connected to the thin-film transistor TFT through the connection metal CM and the drain electrode D to receive a voltage.

The sub-pixel electrode 113 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The sub-pixel electrode 113 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. However, a configuration and a material of the sub-pixel electrode 113 are not limited thereto, and various modifications may be made.

A bank layer 111 may be located on the organic insulating layer 109. For example, the bank layer 111 may be located on the second organic insulating layer 2109. The bank layer 111 may cover an edge (or an edge portion) of the sub-pixel electrode 113. In other words, the bank layer 111 may have an opening through which a central portion of the sub-pixel electrode 113 is exposed. A size and a shape of an emission area of the organic light-emitting diode OLED may be determined by the opening of the bank layer 111.

An intermediate layer 115 may be located on the sub-pixel electrode 113. The intermediate layer 115 may include an organic emission layer including a low molecular weight material or a high molecular weight material. In some embodiments, the intermediate layer 115 may include a single or multi-layer structure including at least one of a hole injection layer, a hole transport layer, an organic emission layer, an electron transport layer, and/or an electron injection layer.

A counter electrode 117 may be located on the intermediate layer 115. In some embodiments, the counter electrode 117 may be located over the entire display area DA. The counter electrode 117 may include a conductive material having a low work function. For example, the counter electrode 117 may include a (semi-) transparent layer including silver (Ag), magnesium (Mg), aluminum (AI), platinum (Pt), palladium (Pd), gold (Au), nickel (Ni), neodymium (Nd), iridium (Ir), chromium (Cr), lithium (Li), calcium (Ca), or an alloy thereof. In an embodiment, the counter electrode 117 may further include a layer including ITO, IZO, ZnO, or In₂O₃ on the (semi-) transparent layer.

An encapsulation layer TFE may be located on the counter electrode 117. The encapsulation layer TFE may include at least one inorganic layer and at least one organic layer. In an embodiment, the encapsulation layer TFE may include first and second inorganic encapsulation layers 119 and 123 and an organic encapsulation layer 121 located between the first and second inorganic encapsulation layers 119 and 123. Each of the first and second inorganic encapsulation layers 119 and 123 may include at least one inorganic insulating material such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The organic encapsulation layer 121 may include a polymer-based material. Examples of the polymer-based material may include a silicon-based resin, an acrylic resin, an epoxy-based resin, polyimide, and polyethylene.

Although not shown in FIG. 2, in another embodiment, a capping layer may be additionally located between the counter electrode 117 and the encapsulation layer TFE.

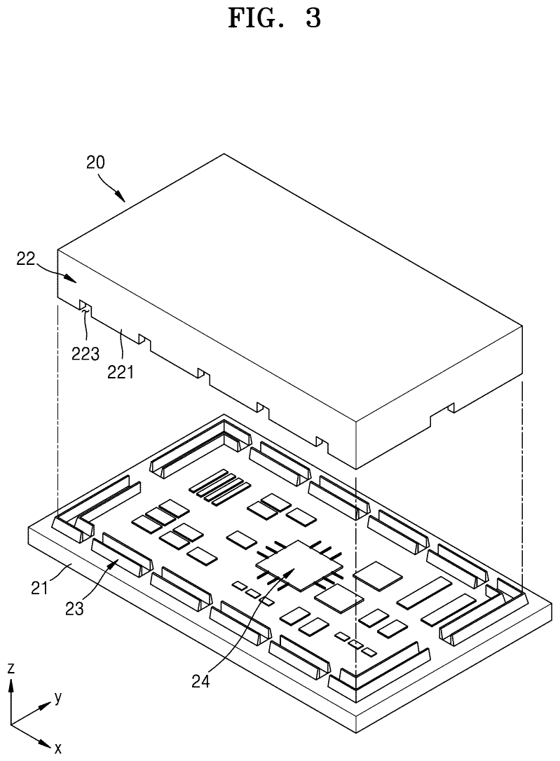

FIG. 3 is an exploded perspective view schematically illustrating the display circuit board 20, according to an embodiment.

Referring to FIG. 3, the display circuit board 20 may include a circuit board 21, a cover portion 22, a support portion 23, and electronic components 24.

The circuit board 21 may provide a base on which the electronic components 24 may be located, and may have a substantially rectangular parallelepiped shape with surfaces extending in the +x direction and the ±y direction in a plan view. The circuit board 21 may include a metal such as copper (Cu), tin (Sn), or gold (Au), and may include a circuit pattern formed on the circuit board 21. The circuit board 21 may include a protective coating for protecting the circuit pattern, for example, photo solder resist (PSR) ink. In some embodiments, the circuit board 21 may be rigid or flexible.

Various electronic components 24 may be mounted on the circuit board 21. The electronic components 24 illustrated in FIG. 3 are an embodiment, and the disclosure is not limited to the number, shape, and pattern of the electronic components 24 illustrated in FIG. 3.

The cover portion 22 may be located on the circuit board 21 to cover the electronic components 24. In some embodiments, the cover portion 22 may be coupled to the circuit board 21. The cover portion 22 may block electromagnetic waves or noise generated from the electronic components 24 to reduce the influence of the electromagnetic waves or the noise on other adjacent components. In some embodiments, the cover portion 22 may be a shield can. In some embodiments, the cover portion 22 may include a metal and may have a rigid structure. In some embodiments, the cover portion 22 may have a flexible structure that may be bent together with the circuit board 21.

The support portion 23 may be located on the circuit board 21, and may protrude toward the cover portion 22, for example, in the +z direction. In case that the cover portion 22 is located on the circuit board 21, the support portion 23 may firmly fix the cover portion 22 on the circuit board 21. In some embodiments, multiple support portions 23 may be provided and may be arranged along a circumference of the circuit board 21. In some embodiments, the support portion 23 may surround the electronic components 24 in a plan view. In some embodiments, in a plan view, the support portion 23 may extend in a direction, for example, the ±x direction or the ±y direction, parallel to a side of the circuit board. In some embodiments, in a plan view, the support portion 23 may extend in directions, for example, the ±x direction and the ±y direction, parallel to two sides of the circuit board 21 to have a substantially L shape.

The cover portion 22 may include a coupling portion 221 corresponding to the support portion 23. In some embodiments, the cover portion 22 may include the coupling portion 221 protruding toward the support portion 23 or the circuit board 21, for example, in a −z direction. In other words, the cover portion 22 may include multiple grooves 223 formed in the +z direction, and a part of the cover portion 22 located between two adjacent grooves 223 may be the coupling portion 221. In some embodiments, multiple coupling portions 221 may be provided and may be arranged to respectively correspond to multiple support portions 23. Accordingly, the coupling portion 221 and the support portion 23 may have a shape extending in a same direction. For example, the coupling portion 221 may have a linear shape extending along the ±x direction or the ±y direction, or may have a substantially L shape extending along the ±x direction and the ±y direction.

In case that the cover portion 22 is coupled to the circuit board 21, a part of the coupling portion 221 may be accommodated and coupled to the support portion 23, which will be described below in detail.

Although FIG. 3 illustrates that one cover portion 22 covering the entire circuit board 21 is located on one circuit board 21, the disclosure is not limited thereto. In another embodiment, a circuit board may include multiple areas, a corresponding electronic component and a cover portion may be located in some areas, and an electronic component and/or a cover portion may not be located in some areas.

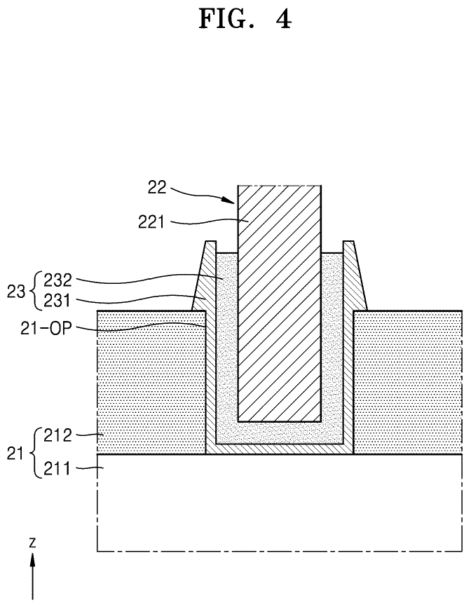

FIG. 4 is a schematic cross-sectional view illustrating a state where the cover portion 22 and the circuit board 21 are coupled to each other, according to a first embodiment.

Referring to FIG. 4, the circuit board 21 may include a receiving portion 21-OP in which a part of the coupling portion 221 may be located. The receiving portion 21-OP may be an opening formed in the circuit board 21. In some embodiments, the circuit board 21 may include multiple layers, for example, a first layer 211 and a second layer 212. In some embodiments, the first layer 211 and the second layer 212 may include different materials. For example, the first layer 211 may include a metal and may be a layer on which a circuit pattern is formed. The second layer 212 may be a layer for protecting the first layer 211 and may include a photo solder resist.

In some embodiments, as shown in FIG. 4, the receiving portion 21-OP may be formed only in the second layer 212 and may pass through the second layer 212. In another embodiment, unlike in FIG. 4, the receiving portion 21-OP may be formed in the second layer 212 and the first layer 211, and the receiving portion 21-OP may pass through the second layer 212 but may not pass through the first layer 211.

The support portion 23 may include a first support portion 231 and a second support portion 232.

A part of the first support portion 231 may be located in the receiving portion 21-OP and may be located on the circuit board 21. The first support portion 231 may cover a side surface of the second layer 212 and a top surface of the first layer 211. The first support portion 231 may contact (e.g., directly contact) the top surface of the first layer 211. A part of the first support portion 231 may protrude in the +z direction beyond a top surface of the circuit board 21 (e.g., a top surface of the second layer 212), and may cover a part of the top surface of the circuit board 21 (e.g., the top surface of the second layer 212). Although FIG. 4 illustrates that the part of the first support portion 231 protruding beyond the top surface of the second layer 212 has a tapered side surface with respect to the top surface of the second layer 212, the disclosure is not necessarily limited thereto. The first support portion 231 may have a substantially constant thickness in the receiving portion 21-OP. Accordingly, the receiving portion 21-OP may be defined by an opening formed in the circuit board 21, and another opening may be defined by the first support portion 231 having a substantially constant thickness in the receiving portion 21-OP. The first support portion 231 may include a metal. In some embodiments, the first support portion 231 may include gold (Au).

A part of the coupling portion 221 may be located in the opening defined by the receiving portion 21-OP or the first support portion 231. In other words, the first support portion 231 may be located between the coupling portion 221 and the receiving portion 21-OP.

The second support portion 232 may be located between the coupling portion 221 and the first support portion 231. In some embodiments, the second portion 232 may fill a space between the coupling portion 221 and the opening defined by the first support portion 231. In some embodiments, the second support portion 232 may include a metal. In some embodiments, the second support portion 232 and the first support portion 231 may include different metals. In some embodiments, the second support portion 232 may include a solder. In some embodiments, the solder of the second support portion 232 may include lead (Pb).

A part of the first support portion 231 may be located in the receiving portion 21-OP of the circuit board 21 and fixed to the circuit board 21, and the coupling portion 221 may be fixed to the first support portion 231 through the second support portion 232. Accordingly, the coupling portion 221 may be coupled to the receiving portion 21-OP through the first support portion 231 and the second support portion 232, and as a result, may be fixed to the circuit board 21.

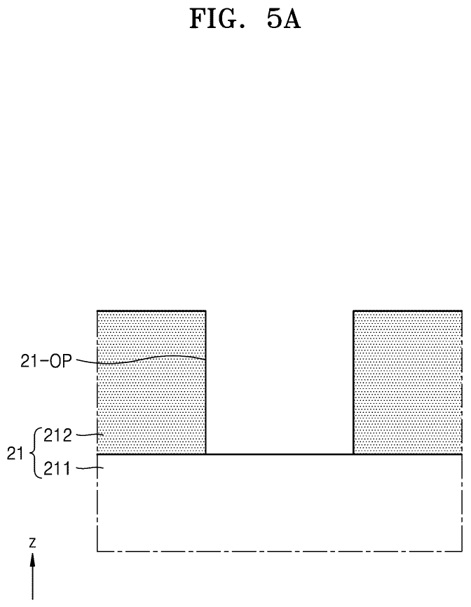

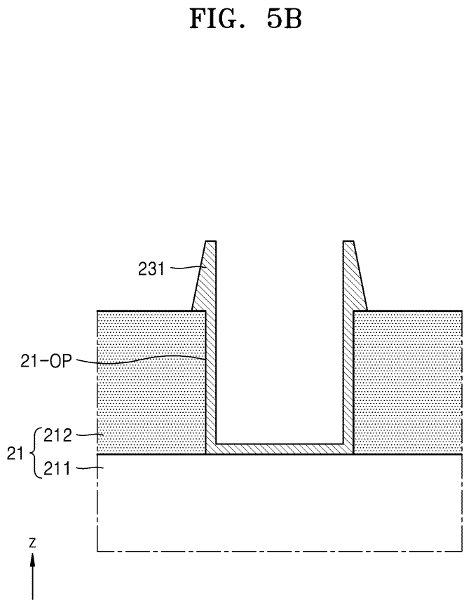

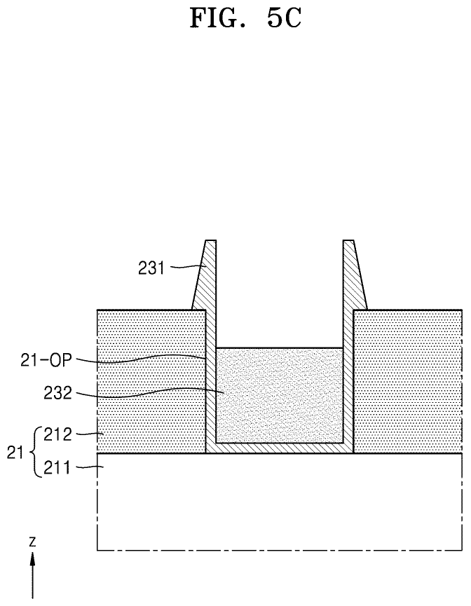

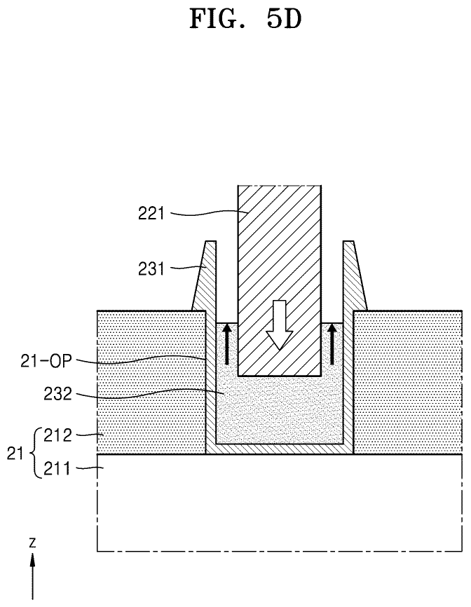

FIGS. 5A to 5D are schematic cross-sectional views illustrating a process of manufacturing the electronic device 1, according to the first embodiment. Hereinafter, a process described with reference to FIGS. 5A to 5D may be a process of implementing the first embodiment of FIG. 4 by coupling the cover portion 22 (see FIG. 4) to the circuit board 21 (see FIG. 4).

Referring to FIG. 5A, the receiving portion 21-OP may be formed by opening a part of the circuit board 21. In some embodiments, a process of forming the receiving portion 21-OP may include etching, for example, dry etching or wet etching. The receiving portion 21-OP may pass through the second layer 212, and thus, a part of a top surface of the first layer 211 may be exposed.

Referring to FIG. 5B, the first support portion 231 may be formed on the circuit board 21. A process of forming the first support portion 231 may include a plating process. In some embodiments, the first support portion 231 may be formed through a plating process such as metal precipitation or electrodeposition. The first support portion 231 may include, but is not limited to, gold (Au) atoms. In some embodiments, the first support portion 231 may cover an entire side surface of the second layer 212 facing the receiving portion 21-OP. In some embodiments, the first support portion 231 may cover the top surface of the first layer 211 exposed by the receiving portion 21-OP.

Referring to FIG. 5C, the second support portion 232 may be provided in an opening defined by the receiving portion 21-OP or the first support portion 231. In some embodiments, the second support portion 232 may include a solder. At a current step of the process, the second support portion 232 may be in a molten state, for example, in a liquid state. Accordingly, in other words, the second support portion 232 may be in the first support portion 231. Although a top surface of the second support portion 232 is lower than a top surface of the second layer 212 (the −z direction) in FIG. 5C, the disclosure is not necessarily limited thereto.

Referring to FIG. 5D, the coupling portion 221 may be moved downward (in the −z direction) into the second support portion 232. At a current step of the process, because the second support portion 232 is in a liquid state, as the coupling portion 221 moves downward (in the −z direction), the second support portion 232 may be pushed around by a volume of the coupling portion 221 immersed in the second support portion 232. Accordingly, as the coupling portion 221 moves downward (in the −z direction), a position of a top surface of the second support portion 232 may move upward (in the +z direction). In other words, a level of the second support portion 232 may rise. While the coupling portion 221 is moved to a desired position in the receiving portion 21-OP, a volume of the second support portion 232 may be appropriately adjusted so that a top surface of the second support portion 232 is not higher than a top surface of the first support portion 231. For example, a volume of the second support portion 232 provided in the step of FIG. 5C may be appropriately adjusted so that the second support portion 232 does not overflow. After the coupling portion 221 is lowered to the desired position, the second support portion 232 may be cured to fix the coupling portion 221 to the first support portion 231 and further to the receiving portion 21-OP, thereby implementing the embodiment of FIG. 4.

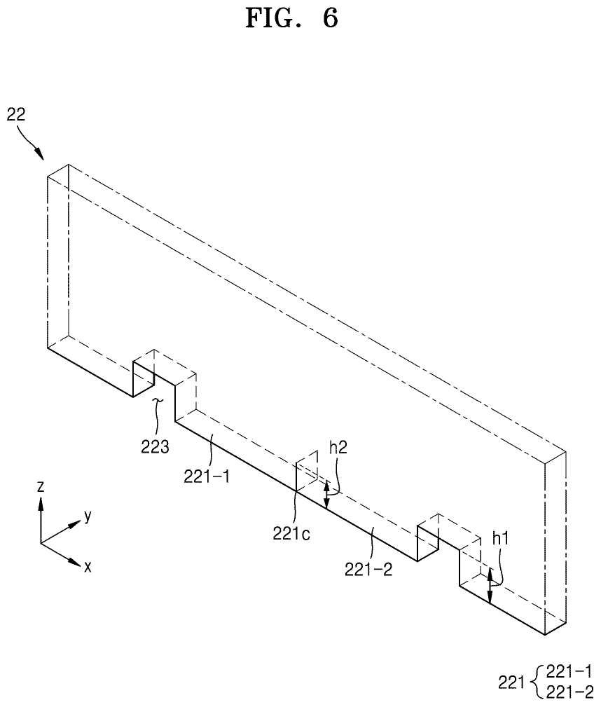

FIG. 6 is an enlarged perspective view illustrating a part of the cover portion 22, according to a second embodiment.

Referring to FIG. 6, a part of the coupling portion 221 may be cut. For example, the coupling portion 221 may include a cut portion 221c located at a central portion in the ±x direction. In some embodiments, the cut portion 221c may be formed along the entire thickness direction of the coupling portion 221 (e.g., in the ±y direction). Accordingly, the cut portion 221c may pass through the coupling portion 221 along the ty direction, and may not pass through the coupling portion 221 along the +z direction.

The coupling portion 221 may be divided into a first coupling portion 221-1 and a second coupling portion 221-2 by the cut portion 221c. In some embodiments, the coupling portion 221 may include the first coupling portion 221-1 located in the −x direction and the second coupling portion 221-2 located in the ±x direction with respect to the cut portion 221c. In some embodiments, a length of the first coupling portion 221-1 in the ±x direction and a length of the second coupling portion 221-2 in the ±x direction may be substantially the same.

A height of the cut portion 221c (or a length in the ±z direction) may be less than a height of the coupling portion (or a length in the ±z direction). In some embodiments, a height h2 of the cut portion 221c may be less than a height h1 of the coupling portion 221 or a height h1 of the groove 223. Accordingly, a part of the coupling portion 221 may be divided into the first coupling portion 221-1 and the second coupling portion 221-2 with respect to the cut portion 221c, and other parts may be integrally formed.

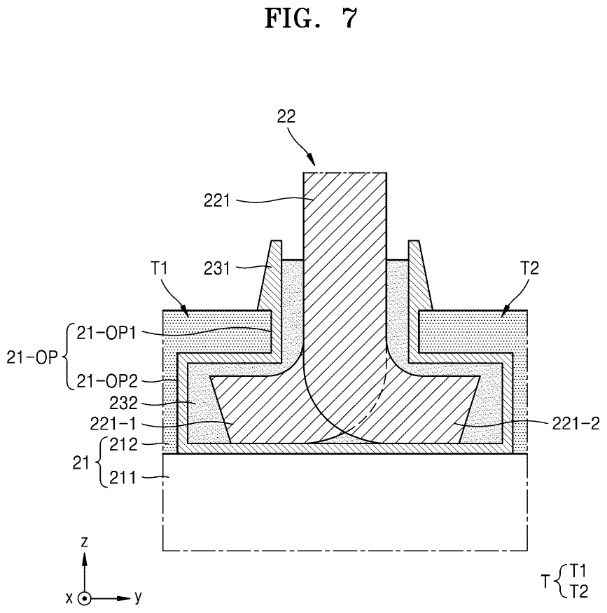

FIG. 7 is a schematic cross-sectional view illustrating a state where the cover portion 22 and the circuit board 21 are coupled to each other, according to the second embodiment.

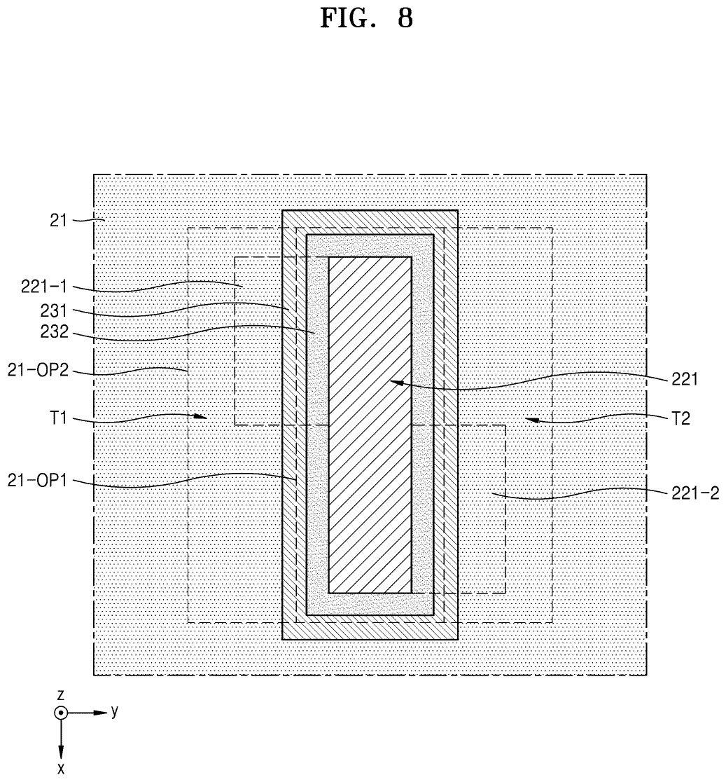

FIG. 8 is a plan view illustrating a state where the cover portion 22 and the circuit board 21 are coupled to each other, according to the second embodiment.

Referring to FIGS. 7 and 8, the circuit board 21 may include an undercut structure. In some embodiments, the receiving portion 21-OP may have a substantially T shape in a cross-sectional view. For example, the receiving portion 21-OP may include a first opening 21-OP1 and a second opening 21-OP2. A width of the first opening 21-OP1 (or a length in the ±y direction) may be less than a width of the second opening 21-OP2 (or a length in the ±y direction). The first opening 21-OP1 may be located higher in the +z direction than the second opening 21-OP2. In other words, the second layer 212 may define a space having a substantially T shape by the receiving portion 21-OP formed in the second layer 212.

Accordingly, the circuit board 21 or the second layer 212 may include a tip T protruding toward the receiving portion 21-OP. In some embodiments, the second layer 212 may include a first tip T1 and a second tip T2 defining the first opening 21-OP1. The first tip T1 may be located on a −y side of the first opening 21-OP1. The second tip T2 may be located on a +y side of the first opening 21-OP1.

The first support portion 231 may be located on the first layer 211 and the second layer 212. Because the receiving portion 21-OP may pass through the second layer 212, the first support portion 231 may contact (e.g., directly contact) a top surface of the first layer 211 and may cover the top surface of the first layer 211. The first support portion 231 may cover a side surface of the second layer 212 facing the second opening 21-OP2. The first support portion 231 may cover a side surface of the second layer 212 facing the first opening 21-OP1, for example, a side surface of the tip T. The first support portion 231 may also cover a bottom surface of the tip T. The first support portion 231 may protrude beyond a top surface of the second layer 212, as described with reference to FIG. 4. A thickness of the first support portion 231 may be substantially constant. Accordingly, the first support portion 231 may define a space having a substantially T shape, like the receiving portion 21-OP.

The coupling portion 221 may be bent in the receiving portion 21-OP. The coupling portion 221 may include the first coupling portion 221-1 and the second coupling portion 221-2. In some embodiments, the first coupling portion 221-1 and the second coupling portion 221-2 may be bent and extend in different directions. In some embodiments, the coupling portion 221 may extend along the ±z direction, and the first coupling portion 221-1 may be bent and extend in substantially the −y direction and the second coupling portion 221-2 may be bent and extend in substantially the ±y direction. The first coupling portion 221-1 may extend further in the −x direction than the second coupling portion 221-2.

A part of the coupling portion 221 may be located in the second opening 21-OP2 or below the tip T. A part of the first coupling portion 221-1 may overlap the first tip T1 in a plan view and may be located below the first tip T1. A part of the second coupling portion 221-2 may overlap the second tip T2 in a plan view and may be located below the second tip T2.

However, the disclosure is not limited thereto. In another embodiment, the first coupling portion 221-1 may be bent in the +y direction and may be located below the second tip T2, and the second coupling portion 221-2 may be bent in the −y direction and may be located below the first tip T1.

The second support portion 232 may be located between the first support portion 231 and the coupling portion 221. In some embodiments, the second support portion 232 may fill a space between the first support portion 231 and the coupling portion 221.

The coupling portion 221 may be fixed to the circuit board 21 through the first support portion 231 and the second support portion 232. Furthermore, due to this bent structure of the coupling portion 221, even in case that an external force (e.g., a force in the +z direction) is applied, the first coupling portion 221-1 and/or the second coupling portion 221-2 may be fixed by the tip T. Due to the this structure, even in case that a considerable external force is applied to the coupling portion 221 and further to the cover portion 22, the coupling portion 221 and the cover portion 22 may not be separated from the circuit board 21.

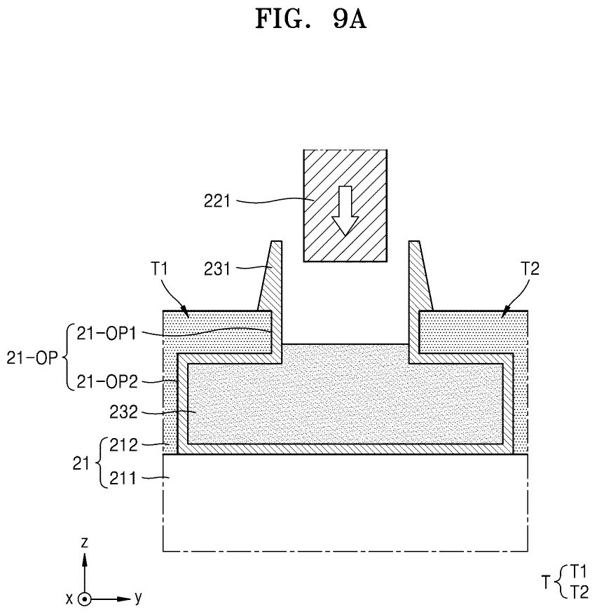

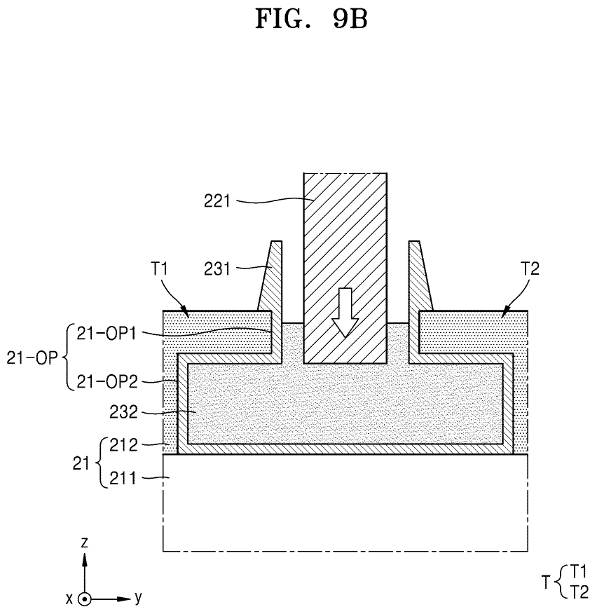

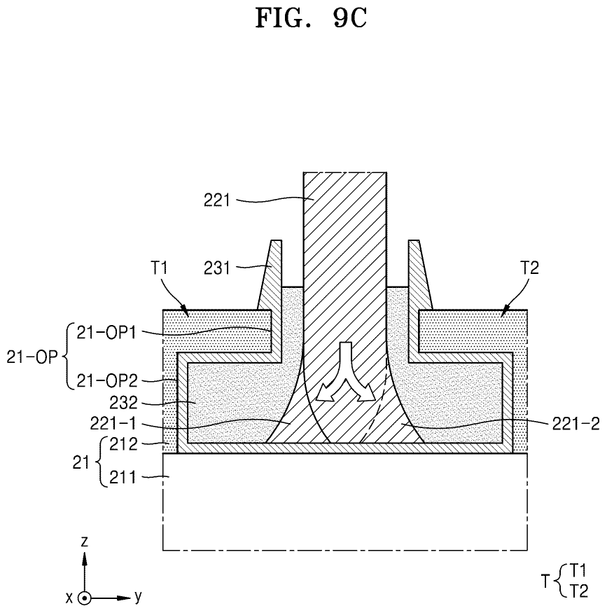

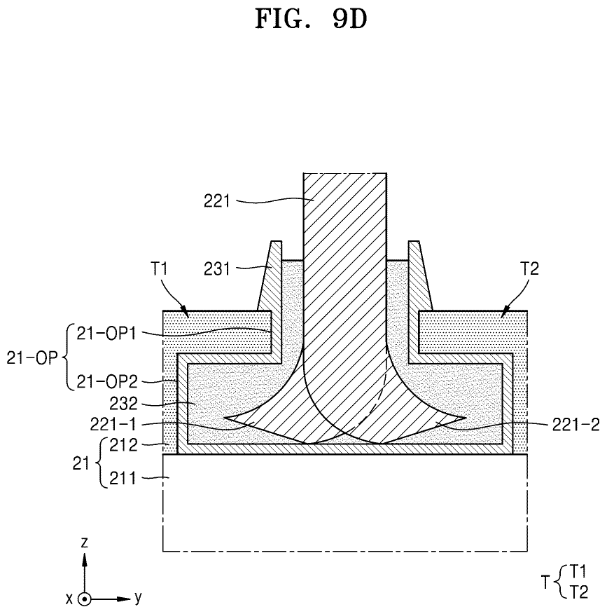

FIGS. 9A to 9D are schematic cross-sectional views illustrating a process of manufacturing the electronic device 1, according to the second embodiment. Hereinafter, a process described with reference to FIGS. 9A to 9D may be a process of implementing the embodiment of FIG. 7 by coupling the cover portion 22 (see FIG. 7) to the circuit board 21 (see FIG. 7).

Referring to FIG. 9A, the receiving portion 21-OP may include the first and second openings 21-OP1 and 21-OP2, and the first support portion 231 may be located to cover a part of a top surface of the second layer 212 and the receiving portion 21-OP. The second support portion 232 may be provided in a space defined by the first support portion 231. In other words, the second support portion 232 may fill a part of the space defined by the first support portion 231. At a current step of the process, the second support portion 232 may be in a liquid state. The coupling portion 221 may be lowered (or moved in the −z direction).

Referring to FIG. 9B, the coupling portion 221 may be further lowered and moved into the second support portion 232. At a current step of the process, because the second support portion 232 is in a liquid state, as the coupling portion 221 moves downward, the second support portion 232 may be pushed around by a volume of the coupling portion 221 immersed in the second support portion 232. Accordingly, as the coupling portion 221 moves downward (in the −z direction), a position of a top surface of the second support portion 232 may move upward (in the +z direction). In other words, a level of the second support portion 232 may rise. While the coupling portion 221 is moved to a desired position in the receiving portion 21-OP, a volume of the second support portion 232 may be appropriately adjusted so that a top surface of the second support portion 232 is higher than a top surface of the first support portion 231. For example, a volume of the second support portion 232 located in the step of FIG. 9A may be appropriately adjusted so that the second support portion 232 does not overflow.

Referring to FIG. 9C, the coupling portion 221 may contact a top surface of the first support portion 231. For example, the coupling portion 221 may be located in the second opening 21-OP2, and may contact a top surface of the first support portion 231 adjacent to a top surface of the first layer 211. Accordingly, the first support portion 231 may no longer move downward (in the −z direction). In this state, in case that a force is continuously applied in the −z direction, the coupling portion 221 may be bent by the force in the −z direction. In embodiments, the coupling portion 221 may include the cut portion 221c (see FIG. 6) described with reference to FIG. 6. Accordingly, the coupling portion 221 may be bent by the force in the −z direction, and the first coupling portion 221-1 and the second coupling portion 221-2 may be bent in different directions. In an embodiment, as shown in FIG. 9C, the first coupling portion 221-1 may be bent toward the −y direction and the second coupling portion 221-2 may be bent toward the +y direction. In another embodiment, unlike in FIG. 9C, the first coupling portion 221-1 may be bent toward the +y direction and the second coupling portion 221-2 may be bent toward the −y direction.

Referring to FIG. 9D, a force may be continuously applied in the −z direction until the coupling portion 221 is bent. Thereafter, the force may be continuously applied in the −z direction until the first coupling portion 221-1 and the second coupling portion 221-2 are located respectively below the first tip T1 and the second tip T2. In other words, the coupling portion 221 may be pushed into the receiving portion 21-OP until considerable portions of the first and second coupling portions 221-1 and 221-2 are located below the tip T. After the first coupling portion 221-1 and the second coupling portion 221-2 are pushed to desired positions, the second support portion 232 may be cured to fix the coupling portion 221. Accordingly, the embodiment of FIG. 7 may be implemented.

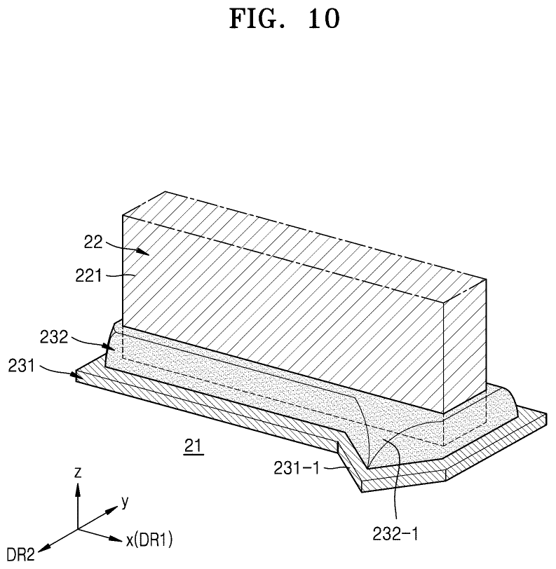

FIG. 10 is a perspective view illustrating a state where the cover portion 22 and the circuit board 21 are coupled to each other, according to a third embodiment.

Referring to FIG. 10, the circuit board 21 may not include an opening, and the first support portion 231 may be located on a top surface of the circuit board 21. The second support portion 232 and the cover portion 22 (or the coupling portion 221) may be located on a top surface of the first support portion 231.

The first support portion 231 may be located (e.g., directly located) on the top surface of the circuit board 21. The first support portion 231 may extend in a direction, for example, a first direction DR1 or the ±x direction. The second support portion 232 and the coupling portion 221 may also extend in the first direction DR1 or the ±x direction. The first support portion 231 may include a first protrusion 231-1 protruding toward a direction, for example, a second direction DR2 (or the −y direction). The first protrusion 231-1 may protrude from an end of the first support portion 231 in the first direction DR1, for example, an end in the ±x direction, toward the second direction DR2.

The coupling portion 221 may be located on the top surface of the first support portion 231, and in some embodiments, may contact (e.g., directly contact) the top surface of the first support portion 231. The coupling portion 221 may not overlap the first protrusion 231-1 of the first support portion 231 in a plan view.

The second support portion 232 may be located on the top surface of the first support portion 231 and may surround a part of a side surface of the coupling portion 221. The second support portion 232 may include a first portion 232-1 located on the first protrusion 231-1 of the first support portion 231. The first portion 232-1 may protrude toward the second direction DR2, like the first protrusion 231-1.

The second support portion 232 may include an inclined side surface. In some embodiments, a height of the first portion 232-1 of the second support portion 232 (a length in the ±z direction) may decrease along the second direction DR2.

An arrangement order of the second support portion 232 and the coupling portion 221 may be similar to that described with reference to FIGS. 5C and 5D. For example, the second support portion 232 that is a liquid solder may be located on the top surface of the first support portion 231. The coupling portion 221 may be lowered to push a part of the second support portion 232 around. After the coupling portion 221 is sufficiently lowered so that the second support portion 232 surrounds the side surface of the coupling portion 221, the second support portion 232 may be cured.

In a step of locating the second support portion 232 in a liquid state on the first support portion 231, a solder may be additionally provided on the first protrusion 231-1 to form the first portion 232-1. The first portion 232-1 may overlap the first protrusion 231-1 in a plan view to increase a thickness of the second support portion 232 in the ±y direction, thereby providing additional support to the coupling portion 221.

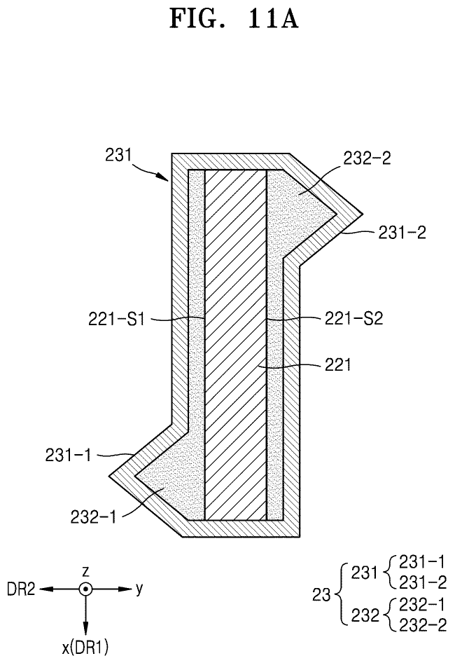

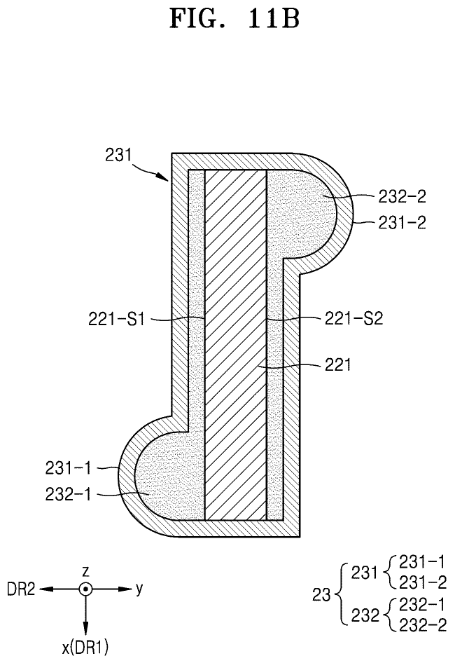

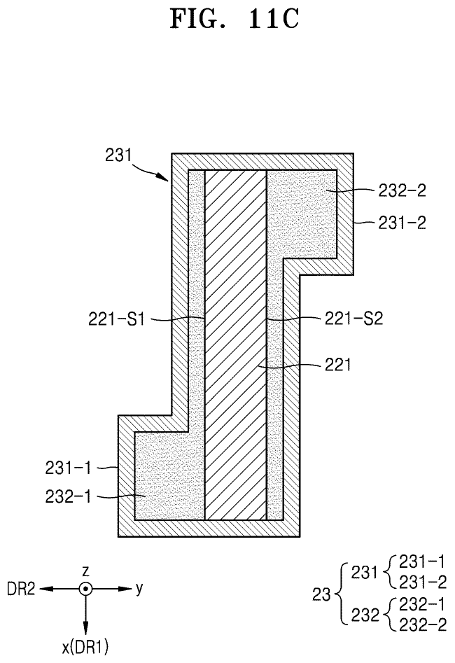

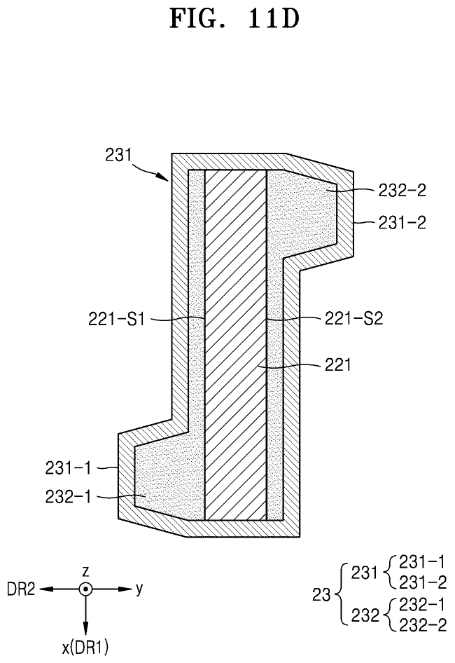

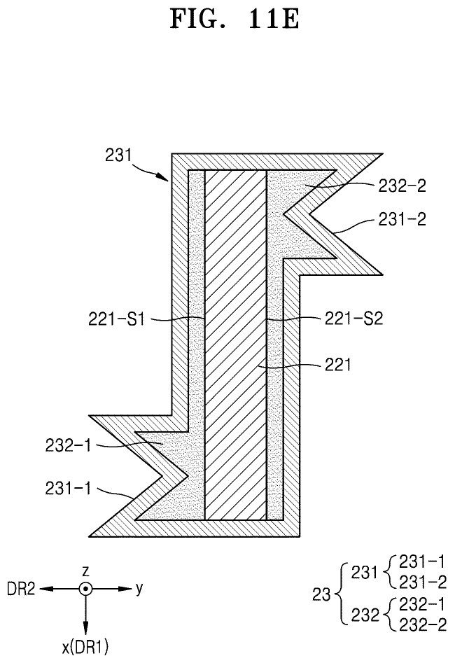

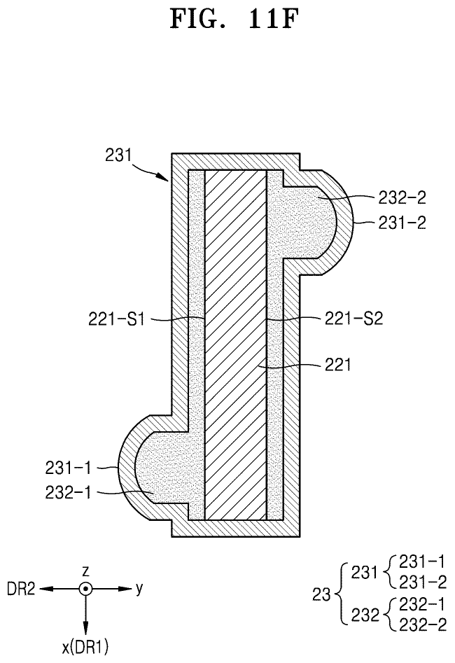

FIGS. 11A to 11F are plan views illustrating a state where the cover portion 22 and the circuit board 21 are coupled to each other, according to various embodiments.

Referring to FIGS. 11A to 11F, the support portion 23 may include the first support portion 231 and the second support portion 232 located on the first support portion 231. The second support portion 232 may surround the coupling portion 221 in a plan view. The first and second support portions 231 and 232 may generally extend in the first direction DR1.

The first support portion 231 may include the first protrusion 231-1 protruding from an end in the +x direction toward the second direction DR2. The first support portion 231 may include the second protrusion 231-2 protruding from an end in the −x direction toward a direction opposite to the second direction DR2 or toward the +y direction. Accordingly, the first protrusion 231-1 and the second protrusion 231-2 may protrude from ends of the first support portion 231 in opposite directions. Although FIGS. 11A to 11F illustrate that the first protrusion 231-1 and the second protrusion 231-2 have similar shapes but extend in opposite directions, the disclosure is not necessarily limited thereto. In some embodiments, the second direction DR2 and the first direction DR1 may be perpendicular to each other.

The second support portion 232 may include the first portion 232-1 protruding from an end in the +x direction toward the second direction DR2 and overlapping the first protrusion 231-1. The second support portion 232 may include the second portion 232-2 protruding from an end in the −x direction toward the +y direction and overlapping the second protrusion 231-2. Accordingly, the first portion 232-1 and the second portion 232-2 may protrude from ends of the second support portion 232 in opposite directions. Although FIGS. 11A to 11F illustrate that the first portion 232-1 and the second portion 232-2 have similar shapes but extend in opposite directions, the disclosure is not necessarily limited thereto. Although FIGS. 11A to 11F illustrate that the first and second portions 232-1 and 232-2 have substantially similar shapes to the first and second protrusions, the disclosure is not necessarily limited thereto.

In some embodiments, the area of the first protrusion 231-1 and the area of the second protrusion 231-2 of the first support portion 231 may be the same in a plan view. In some embodiments, the area (or volume) of the first portion 232-1 and the area (or volume) of the second portion 232-2 of the second portion 232 may be the same in a plan view.

The second support portion 232 may have an additional thickness in the ty direction at an end in the +x direction, due to the first portion 232-1 located on the first protrusion 231-1. The second support portion 232 may have an additional thickness in the ±y direction at an end in the −x direction, due to the second portion 232-2 located on the second protrusion 231-2. Due to the additional thickness (or volume) of the second support portion 232, the coupling portion 221 may receive additional support in the ±y direction. Accordingly, the coupling portion 221 may be more firmly fixed to the first support portion 231 in case that the first and second portions 232-1 and 232-2 of the second support portion 232 are present than in case that the first and second portions 232-1 and 232-2 of the second support portion 232 are not present.

Hereinafter, embodiments of shapes of the first and second protrusions 231-1 and 231-2 of the first support portion 231 and the first and second portions 232-1 and 232-2 of the second support portion 232 will be described in detail with reference to FIGS. 11A to 11F. Although FIGS. 11A to 11F illustrate that the first and second protrusions 231-1 and 231-2 of the first support portion 231 have the same shape and size, the disclosure is not limited thereto, and the first and second protrusions 231-1 and 231-2 may have different shapes and/or sizes. Although FIGS. 11A to 11F illustrate that the first and second portions 232-1 and 232-2 of the second support portion 232 have the same shape and size, the disclosure is not limited thereto, and the first and second portions 232-1 and 232-2 may have different shapes and/or sizes.

Referring to FIG. 11A, the first and second protrusions 231-1 and 231-2 of the first support portion 231 and the first and second portions 232-1 and 232-2 of the second support portion 232 may have substantially triangular shapes in a plan view. Although the first and second protrusions 231-1 and 231-2 and the first and second portions 232-1 and 232-2 have substantially equilateral triangle shapes in FIG. 11A, the disclosure is not limited thereto. In another embodiment, the first and second protrusions 231-1 and 231-2 and the first and second portions 232-1 and 232-2 may have any of various shapes such as right triangle shapes, isosceles triangle shapes, acute triangle shapes, or obtuse triangle shapes.

Referring to FIG. 11B, the first and second protrusions 231-1 and 231-2 of the first support portion 231 and the first and second portions 232-1 and 232-2 of the second support portion 232 may have substantially semicircular shapes in a plan view. Although the first and second protrusions 231-1 and 231-2 and the first and second portions 232-1 and 232-2 have substantially semicircular shapes with smooth surfaces in FIG. 11B, the disclosure is not limited thereto. Various modifications may be made. In another embodiment, the first and second protrusions 231-1 and 231-2 and the first and second portions 232-1 and 232-2 may have semicircular shapes with protrusions formed on half-oval surfaces in a plan view.

Referring to FIG. 11C, the first and second protrusions 231-1 and 231-2 of the first support portion 231 and the first and second portions 232-1 and 232-2 of the second support portion 232 may have substantially quadrangular shapes in a plan view. Although the first and second protrusions 231-1 and 231-2 and the first and second portions 232-1 and 232-2 have substantially rectangular shapes in FIG. 11C, the disclosure is not limited thereto. In another embodiment, the first and second protrusions 231-1 and 231-2 and the first and second portions 232-1 and 232-2 may have any of various shapes such as square shapes, rhombus shapes, parallelogram shapes, or trapezoidal shapes. For example, the first and second protrusions 231-1 and 231-2 and the first and second portions 232-1 and 232-2 may have trapezoidal shapes in a plan view as illustrated in FIG. 11D.

Referring to FIG. 11D, the first and second protrusions 231-1 and 231-2 of the first support portion 231 and the first and second portions 232-1 and 232-2 of the second support portion 232 may have substantially trapezoidal shapes in a plan view. Although lengths of the first and second protrusions 231-1 and 231-2 and the first and second portions 232-1 and 232-2 in the ±x direction decrease away from the coupling portion 221 in FIG. 11D, the disclosure is not limited thereto. In another embodiment, lengths of the first and second protrusions 231-1 and 231-2 and the first and second portions 232-1 and 232-2 in the ±x direction may increase away from the coupling portion 221.

Referring to FIGS. 11E and 11F, the first and second protrusions 231-1 and 231-2 of the first support portion 231 and the first and second portions 232-1 and 232-2 of the second portion 232 may have shapes obtained by combining multiple shapes in a plan view.

For example, referring to FIG. 11E, the first and second protrusions 231-1 and 231-2 and the first and second portions 232-1 and 232-2 may have shapes in which right triangle shapes of the same size are symmetrically arranged around the y axis in a plan view. In FIG. 11E, parts of two right triangle shapes that are symmetrical to each other overlap each other. The two shapes that are symmetrical to each other may have different shapes or sizes.

For example, referring to FIG. 11F, the first and second protrusions 231-1 and 231-2 and the first and second portions 232-1 and 232-2 may have shapes in which a substantially rectangular shape and a semicircular shape are combined in a plan view. The rectangular shape of the first and second protrusions 231-1 and 231-2 and the first and second portions 232-1 and 232-2 may be closer to the coupling portion 221 than the semicircular shape. The rectangular shape may be modified into any of various shapes such as a trapezoidal shape or a parallelogram shape. Also, the semicircular shape may be modified into any of various shapes such as a semielliptical shape.

According to the above embodiments, an electronic device having a structure in which a shield can may be firmly fixed without being separated from a PCB may be provided.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An electronic device comprising:
a display panel;
a circuit board, on which at least one component is mounted and connected to the display panel; and
a cover portion coupled to the circuit board and shield the at least one component, wherein
the cover portion comprises a coupling portion that protrudes,
the circuit board comprises a receiving portion coupled to the coupling portion, and
the coupling portion is accommodated in the receiving portion.

2. The electronic device of claim 1, further comprising:
a first support portion located between the coupling portion and the receiving portion.

3. The electronic device of claim 2, wherein the first support portion comprises gold (Au).

4. The electronic device of claim 1, wherein
the circuit board comprises a plurality of layers comprising different materials, and
the receiving portion passes through at least one of the plurality of layers.

5. The electronic device of claim 2, further comprising:
a second support portion located between the coupling portion and the first support portion.

6. The electronic device of claim 5, wherein the first support portion and the second support portion comprise different materials.

7. The electronic device of claim 5, wherein the second support portion is spaced apart from the circuit board.

8. The electronic device of claim 1, wherein the circuit board further comprises a tip protruding toward the receiving portion.

9. The electronic device of claim 1, wherein at least a portion of the coupling portion is bent.

10. The electronic device of claim 1, wherein the coupling portion comprises a first coupling portion and a second coupling portion bent from a part of the coupling portion in different directions.

11. The electronic device of claim 10, wherein
at least a part of the first coupling portion is located below a first tip protruding from a side surface of the circuit board facing the receiving portion toward the receiving portion, and
at least a part of the second coupling portion is located below a second tip facing the first tip with the receiving portion between the first tip and the second tip.

12. The electronic device of claim 1, wherein
the coupling portion comprises a plurality of coupling portions,
the receiving portion comprises a plurality of receiving portions,
the plurality of coupling portions are spaced apart from each other, and
the plurality of receiving portions are arranged to respectively correspond to the plurality of coupling portions.

13. An electronic device comprising:
a display panel;
a circuit board, on which at least one component is mounted and connected to the display panel;
a cover portion coupled to the circuit board, shield the at least one component, and comprising a coupling portion protruding toward the circuit board; and
a first support portion located between the coupling portion and the circuit board,
wherein, in a plan view, the first support portion comprises:
a first protrusion protruding from a first end of the first support portion in a first direction in which the first support portion extends toward a second direction different from the first direction; and
a second protrusion protruding from a second end of the first support portion opposite to the first end toward a direction opposite to the second direction.

14. The electronic device of claim 13, wherein the first direction and the second direction are perpendicular to each other.

15. The electronic device of claim 13, wherein an area of the first protrusion and an area of the second protrusion are equal to each other in a plan view.

16. The electronic device of claim 13, wherein the first support portion comprises gold (Au).

17. The electronic device of claim 13, further comprising:
a second support portion located on the first support portion and surrounding a part of a side surface of the coupling portion.

18. The electronic device of claim 17, wherein the first support portion and the second support portion comprise different materials.

19. The electronic device of claim 17, wherein the second support portion comprises a first portion overlapping the first protrusion and a second portion overlapping the second protrusion in a plan view.

20. The electronic device of claim 13, wherein
the coupling portion comprises a plurality of coupling portions,
the first support portion comprises a plurality of first support portions,
the plurality of coupling portions are spaced apart from each other, and
the plurality of first support portions are arranged to respectively correspond to the plurality of coupling portions.
